(19) United States
(12) Patent Application Publication
(10) Pub. No.: US 2009/0079341 A1
(43) Pub. Date: Mar. 26, 2009

(54) BACKPLANE STRUCTURES FOR SOLUTION PROCESSED ELECTRONIC DEVICES

(76) Inventor: YAW-MING A. TSAI, Santa Barbara, CA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 12/237,496

(22) Filed: Sep. 25, 2008

Related U.S. Application Data
(60) Provisional application No. 60/974,990, filed on Sep. 25, 2007.

(51) Int. Cl. H01J 1/63; H01J 9/00; H01L 29/04

(52) U.S. Cl. 313/504; 445/46; 257/59; 257/E29.004

(57) ABSTRACT

There is provided a backplane for an organic electronic device. The backplane has a TFT substrate; a thick organic planarization layer; a multiplicity of electrode structures; and a thin insulative inorganic bank structure defining a multiplicity of pixel openings on the electrode structures.

### RELATED APPLICATION DATA

This application claims priority under 35 U.S.C. § 119(e) from Provisional Application No. 60/974,990 filed Sep. 25, 2007 which is incorporated herein by reference in its entirety.

### BACKGROUND INFORMATION

1. Field of the Disclosure

This disclosure relates in general to electronic devices and processes for forming the same. More specifically, it relates to backplane structures and devices formed by solution processing using the backplane structures.

2. Description of the Related Art

Electronic devices, including organic electronic devices, continue to be more extensively used in everyday life. Examples of organic electronic devices include organic light-emitting diodes (“OLEDs”). A variety of deposition techniques can be used in forming layers used in OLEDs. Liquid deposition techniques include printing techniques such as ink-jet printing and continuous nozzle printing.

As the devices become more complex and achieve greater resolution, the use of active matrix circuitry with thin film transistors (“TFTs”) becomes more necessary. However, surfaces of most TFT substrates are not planar. Liquid deposition onto these non-planar surfaces can result in non-uniform films. The non-uniformity may be mitigated by the choice of solvent for the coating formulation and/or by controlling the drying conditions. However, there still exists a need for a TFT substrate design that will result in improved film uniformity.

### SUMMARY

In an embodiment, there is provided a process for forming a backplane for an organic electronic device, the process comprising:

providing a TFT substrate;

forming a thick organic planarization layer over the substrate;

forming a multiplicity of electrode structures on the planarization layer; and

forming a thin layer of insulative inorganic bank structure defining pixel areas over the electrode structures.

There is also provided a backplane for an organic electronic device comprising:

a TFT substrate;

a thick organic planarization layer;

a multiplicity of electrode structures; and

a thin insulative inorganic bank structure defining a multiplicity of pixel openings on the electrode structures.

There is also provided a process for forming an organic electronic device, said process comprising:

forming a backplane comprising:
a TFT substrate;
a thick organic planarization layer;
a multiplicity of electrode structures; and
a thin insulative inorganic bank structure defining a multiplicity of pixel openings on the electrode structures;

depositing into at least a portion of the pixel openings a first liquid composition comprising a first active material in a liquid medium.

The foregoing general description and the following detailed description are exemplary and explanatory only and are not restrictive of the scope of the appended claims.

### BRIEF DESCRIPTION OF THE DRAWINGS

Embodiments are illustrated in the accompanying figures to assist in understanding concepts presented in the disclosure.

FIG. 1 includes as illustration a schematic diagram of a backplane for an electronic device, as described herein.

FIG. 2 includes as illustration another schematic diagram of a backplane for an electronic device, as described herein.

Skilled artisans will appreciate that objects in the figures are illustrated for simplicity and clarity and have not necessarily been drawn to scale. For example, the dimensions of some of the objects in the figures may be magnified relative to other objects to help to improve understanding of embodiments.

### DETAILED DESCRIPTION

Many aspects and embodiments are described throughout the disclosure and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Process for Forming a Backplane, the Backplane, and the Process for Forming an Electronic Devices.

### 1. Definitions and Clarification of Terms

Before addressing details of embodiments described below, some terms are defined or clarified. Definitions include variants, such as inflected forms, of the defined terms.

As used herein, the term “active” when referring to a layer or material refers to a layer or material which electronically facilitates the operation of the device. Examples of active materials include, but are not limited to, materials that conduct, inject, transport, or block a charge, where the charge can be either an electron or a hole. Examples also include a layer or material that has electronic or electro-radiative properties. An active layer material may emit radiation or exhibit a change in concentration of electron-hole pairs when receiving radiation.

The term “active matrix” is intended to mean an array of electronic components and corresponding driver circuits within the array.

The term “backplane” is intended to mean a workpiece on which organic layers can be deposited to form an electronic device.

The term “circuit” is intended to mean a collection of electronic components that collectively, when properly connected and supplied with the proper potential(s), performs a function. A circuit may include an active matrix pixel within an array of a display, a column or row decoder, a column or row array strobe, a sense amplifier, a signal or data driver, or the like.

The term “connected,” with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both are not considered electronic components for the purposes of this definition. In one embodiment, electronic components are connected when they are electrically shorted to one another and lie at substantially the same voltage. Note that electronic components can be connected together using fiber optic lines to allow optical signals to be transmitted between such electronic components.

The term “coupled” is intended to mean a connection, linking, or association of two or more electronic components, circuits, systems, or any combination of at least two of: (1) at least one electronic component, (2) at least one circuit, or (3) at least one system in such a way that a signal (e.g., current, voltage, or optical signal) may be transferred from one to another. Non-limiting examples of “coupled” can include direct connections between electronic components, circuits or electronic components with switch(es) (e.g., transistor(s)) connected between them, or the like.

The term “driver circuit” is intended to mean a circuit configured to control the activation of an electronic component, such as an organic electronic component.

The term “electrically continuous” is intended to mean a layer, member, or structure that forms an electrical conduction path without an electrical open circuit.

The term “electrode” is intended to mean a structure configured to transport carriers. For example, an electrode may be an anode or a cathode. Electrodes may include parts of transistors, capacitors, resistors, inductors, diodes, organic electronic components and power supplies.

The term “electronic component” is intended to mean a lowest level unit of a circuit that performs an electrical function. An electronic component may include a transistor, a diode, a resistor, a capacitor, an inductor, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “electronic device” is intended to mean a collection of circuits, electronic components, or combinations thereof that collectively, when properly connected and supplied with the proper potential(s), performs a function. An electronic device may include, or be part of, a system. Examples of electronic devices include displays, sensor arrays, computer systems, avionics, automobiles, cellular phones, and many other consumer and industrial electronic products.

The term “insulative” is used interchangeably with “electrically insulating”. These terms and their variants are intended to refer to a material, layer, member, or structure having an electrical property such that it substantially prevents any significant current from flowing through such material, layer, member or structure.

The term “layer” is used interchangeably with the term “film” and refers to a coating covering a desired area. The area can be as large as an entire device or as small as a specific functional area such as the actual visual display, or as small as a single sub-pixel. Films can be formed by any conventional deposition technique, including vapor deposition, liquid deposition and thermal transfer. Typical liquid deposition techniques include, but are not limited to, continuous deposition techniques such as spin coating, gravure coating, curtain coating, dip coating, slot-die coating, spray coating, and continuous nozzle coating; and discontinuous deposition techniques such as ink jet printing, gravure printing, and screen printing.

The term “light-transmissive” is used interchangeably with “transparent” and is intended to mean that at least 50% of incident light of a given wavelength is transmitted. In some embodiments, 70% of the light is transmitted.

The term “liquid composition” is intended to mean an organic active material that is dissolved in a liquid medium or media to form a solution, dispersed in a liquid medium or media to form a dispersion, or suspended in a liquid medium or media to form a suspension or an emulsion.

The term “opening” is intended to mean an area characterized by the absence of a particular structure that surrounds the area, as viewed from the perspective of a plan view.

The term “organic electronic device” is intended to mean a device including one or more semiconductor layers or materials. Organic electronic devices include: (1) devices that convert electrical energy into radiation (e.g., an light-emitting diode, light emitting diode display, or diode laser), (2) devices that detect signals through electronics processes (e.g., photodetectors (e.g., photoconductive cells, photoresistors, photoswitches, phototransistors, or phototubes), IR detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The term “overlying,” when used to refer to layers, members or structures within a device, does not necessarily mean that one layer, member or structure is immediately next to or in contact with another layer, member, or structure.

The term “perimeter” is intended to mean a boundary of a layer, member, or structure that, from a plan view, forms a closed planar shape.

The term “photoresist” is intended to mean a photosensitive material that can be formed into a layer. When exposed to activating radiation, at least one physical property and/or chemical property of the photoresist is changed such that the exposed and unexposed areas can be physically differentiated.

The term “structure” is intended to mean one or more patterned layers or members, which by itself or in combination with other patterned layer(s) or member(s), forms a unit that serves an intended purpose. Examples of structures include electrodes, well structures, cathode separators, and the like.

The term “TFT substrate” is intended to mean an array of TFTs and/or driving circuitry to make panel function on a base support.

The term “support” or “base support” is intended to mean a base material that can be either rigid or flexible and may be include one or more layers of one or more materials, which can include, but are not limited to, glass, polymer, metal or ceramic materials or combinations thereof.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited in case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Process for Forming a Backplane

It has been known to use an organic bank layer having a thickness of about a few microns over an electrode pattern on a TFT substrate to provide physical containment for solution processing in later steps. However, when the active layers of devices are applied by liquid processing techniques, the thick organic bank layer can have disadvantages. The bank created around the pixel areas results in non-uniformities of the active layers, which in turn leads to poor lifetimes for the device. The organic material of the bank layer can easily absorb liquid from the cleaning process or the deposition process. This can be detrimental to device lifetime and can result in the need for longer baking times in processing. In addition, the etching selectivity between the active materials and the organic bank materials is low. This may result in the presence of organic bank material in the sealing areas and cause poor sealing, which also adversely affects lifetime.

It has also been known to use inorganic planarization layers having a thickness of about 3000-4000 Å over the TFT substrate and provide the electrode structure over this layer. These thin layers sometimes do not adequately lower the parasitic capacitance. In addition, the materials used to pattern the electrodes may cause defects in the TFT electrodes, and may even result in shorting. In some cases, this planarization may not be sufficient to cover the rough features or particulate materials that are on the TFT substrate. In addition, the aperture ratio may be reduced.

There is provided herein an improved process for forming a backplane for an electronic device. The process comprises:

providing a TFT substrate;

forming a thick organic planarization layer over the substrate;

forming a multiplicity of electrode structures on the planarization layer; and

forming a thin layer of insulative inorganic bank structure defining pixel areas over the electrode structures.

The new TFT backplane described herein can provide several advantages. The thick organic planarization layer reduces the parasitic capacitance resulting in improved driving capability and reduced power consumption. The thick organic planarization layer also reduces the impact of rough features and/or particles on the TFT substrate. There is a reduction in shorting defects between the pixel electrode and the source/drain and data line metals. There is superior etching selectivity between the organic OLED layers and the inorganic bank. The thin inorganic bank structure enhances printing uniformity. The impact of the organic planarization layer on the active area of the organic device is reduced by the inorganic bank structure. Moisture from the planarization layer is not released into the OLED active layers. A better seal is possible by having the inorganic bank structure in the sealing areas.

TFT substrates are well known in the electronic arts. The base support may be a conventional support as used in organic electronic device arts. The base support can be flexible or rigid, organic or inorganic. In some embodiments, the base support is transparent. In some embodiments, the base support is glass or a flexible organic film. The TFT array may be located over or within the support, as is known. The support can have a thickness in the range of about 12 to 2500 microns.

The term “thin-film transistor” or “TFT” is intended to mean a field-effect transistor in which at least a channel region of the field-effect transistor is not principally a portion of a base material of a substrate. In one embodiment, the channel region of a TFT includes a—Si, polycrystalline silicon, or a combination thereof. The term “field-effect transistor” is intended to mean a transistor, whose current carrying characteristics are affected by a voltage on a gate electrode. A field-effect transistor includes a junction field-effect transistor (JFET) or a metal-insulator-semiconductor field-effect transistor (MISFET), including a metal-oxide-semiconductor field-effect transistor (MOSFETs), a metal-nitride-oxide-semiconductor (MNOS) field-effect transistor, or the like. A field-effect transistor can be n-channel (n-type carriers flowing within the channel region) or p-channel (p-type carriers flowing within the channel region). A field-effect transistor may be an enhancement-mode transistor (channel region having a different conductivity type compared to the transistor's S/D regions) or depletion-mode transistor (the transistor's channel and S/D regions have the same conductivity type).

TFT structures and designs are well known. The TFT structure usually includes gate, source, and drain electrodes, and a sequence of inorganic insulating layers, usually referred to as a buffer layer, gate insulator, and interlayer.

In the process described herein, a thick organic planarization layer is provided over the TFT substrate. As used herein, the term “thick”, when referring to the planarization layer, is intended to mean a thickness of at least 5000 Å in the direction perpendicular to the plane of the substrate. The planarization layer smoothes over the rough features and any particulate material of the TFT substrate, and prevents parasitic capacitance. In some embodiments, the planarization layer is 0.5 to 5 microns in thickness; in some embodiments, 1 to 3 microns.

Any organic dielectric material can be used for the planarization layer. In general, the organic material should have a dielectric constant of at least 2.5. In some embodiments, the organic material is selected from the group consisting of epoxy resins, acrylic resins, and polyimide resins. Such resins are well known, and many are commercially available.

In some embodiments the organic planarization layer is patterned. In some embodiments, the layer is patterned so as to remove it from the areas where the electronic device will be sealed. Patterning can be accomplished using standard photolithographic techniques. In some embodiments, the planarization layer is made from a photosensitive material known as a photoresist. In this case, the layer can be imaged and developed to form the patterned planarization layer. The photoresist can be positive-working, which means that the photoresist layer becomes more removable in the areas exposed to activating radiation, or negative-working, which means this it is more easily removed in the non-exposed areas. In some embodiments, the planarization layer itself is not photosensitive. In this case, a photoresist layer can be applied over the planarization layer, imaged, and developed to form the patterned planarization layer. In some embodiments, the photoresist is then stripped off. Techniques for imaging, developing, and stripping are well known in the photoresist art area.

A multiplicity of electrode structures is then formed on the planarization layer. The electrodes may be anodes or cathodes. In some embodiments, the electrodes are formed as parallel strips. Alternately, the electrodes may be a patterned array of structures having plan view shapes, such as squares, rectangles, circles, triangles, ovals, and the like. Generally, the electrodes may be formed using conventional processes (e.g. deposition, patterning, or a combination thereof).

In some embodiments, the electrodes are transparent. In some embodiments, the electrodes comprise a transparent conductive material such as indium-tin-oxide (ITO). Other transparent conductive materials include, for example, indium-zinc-oxide (IZO), zinc oxide, tin oxide, zinc-tin-oxide (ZTO), elemental metals, metal alloys, and combinations thereof. In some embodiments, the electrodes are anodes for the electronic device. The electrodes can be formed using conventional techniques, such as selective deposition using a stencil mask, or blanket deposition and a conventional lithographic technique to remove portions to form the pattern. The thickness of the electrode is generally in the range of approximately 50 to 150 nm.

A thin layer of insulative inorganic bank structure is then formed to define pixel areas over the electrode structures. As used here, the term “thin”, when referring to the insulative inorganic bank structure, is intended to mean a thickness of no greater than 3000 Å in the direction perpendicular to the plan of the substrate. In some embodiments, the insulative inorganic bank structure is less than 2000 Å; in some embodiments, less than 1500 Å. The lower limit on the thickness of this layer is determined by the level at which the bank structure is functional.

Any insulative inorganic material can be used for the inorganic bank structure. In some embodiments, the inorganic material is a metal oxide or nitride. In some embodiments, the inorganic material is selected from the group consisting of silicon oxides, silicon nitrides, and combinations thereof.

The bank structure is formed in a pattern wherein there is an opening in the pixel areas where organic active material(s) will be deposited. Surrounding each pixel opening is a bank. The bank structure can be formed using conventional techniques, such as selective deposition using a stencil mask, or blanket deposition and a conventional lithographic technique to remove portions to form the pattern.

### 3. The Backplane

There is described herein, a new backplane for an organic electronic device. The backplane is particularly useful for forming devices by solution processing. The backplane comprises:

a TFT substrate;

a thick organic planarization layer;

a multiplicity of electrode structures; and

a thin insulative inorganic bank structure defining a multiplicity of pixel openings on the electrode structures.

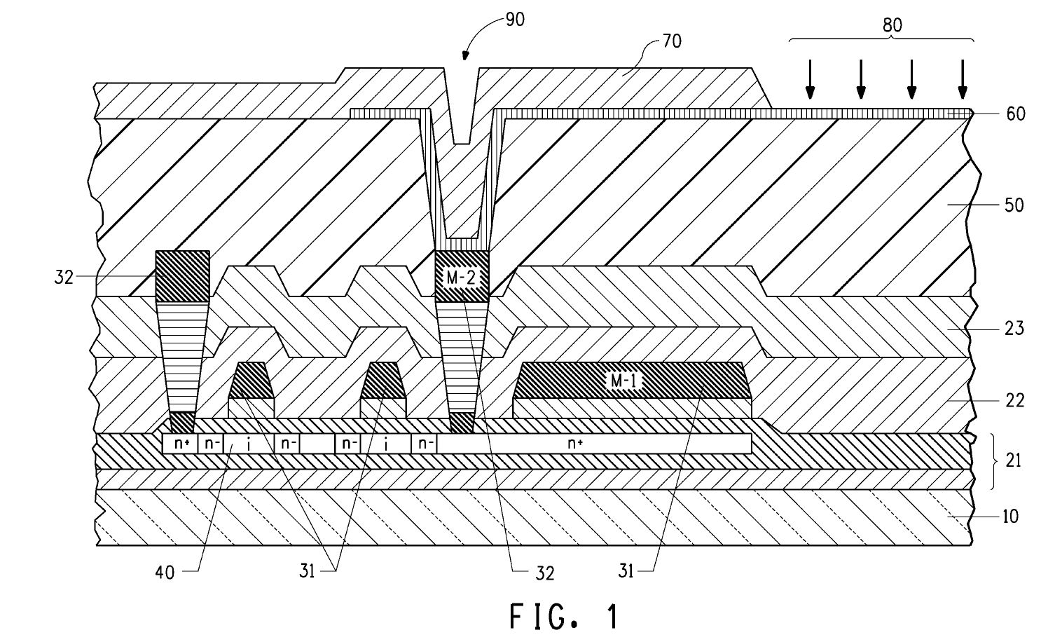

One exemplary backplane with polycrystalline TFTs is shown schematically in FIG. 1. The TFT substrate includes: glass substrate 10, inorganic buffer layer 21, gate insulator layer 22, interlayer 23, gate electrode or gate lines 31, source/drain electrodes or data lines 32, and polysilicon 40. The insulative layers 21, 22, and 23 can be made of any inorganic insulative materials, as is known in the art. The conductive layers 31 and 32 can be made of any inorganic conductive materials, as is known in the art. The doped polysilicon layer is also well known in the art. Over the TFT substrate is organic planarization layer 50. The materials for the planarization layer have been discussed above. The planarization layer is patterned to include via opening 90 and an opening for encapsulation (not shown). A patterned electrode 60 is formed over the planarization layer 50. The materials for the electrode have been discussed above. A bank structure 70 is formed over the electrode layer. The bank defines pixel openings 80, where active organic materials will be deposited to form the device.

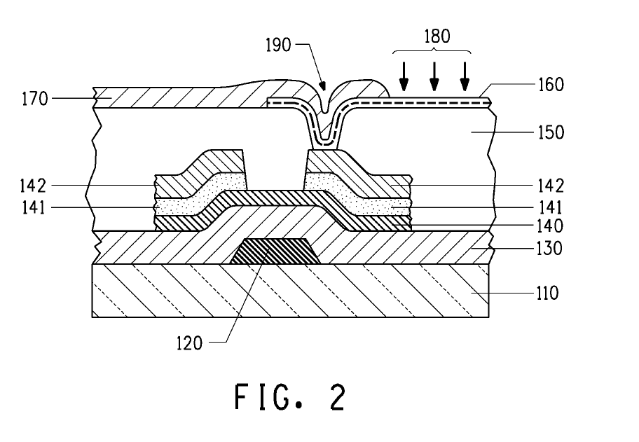

Another exemplary backplane with a—Si TFTs is shown schematically in FIG. 2. The TFT substrate includes: glass substrate 110, gate electrode or gate lines 120, gate insulator layer 130, a—Si channel 140, n⁺ a—Si contacts 141, and source/drain metals 142. The insulative layer 130 can be made of any inorganic insulative material, as is known in the art. The conductive layers 120 and 142 can be made of any inorganic conductive materials, as is known in the art. The a—Si channel and doped n⁺ a—Si layers are also well known in the art. Over the TFT substrate is organic planarization layer 150. The materials for the planarization layer have been discussed above. The planarization layer is patterned to include via opening 190 and an opening for encapsulation (not shown). A patterned electrode 160 is formed over the planarization layer 150. The materials for the electrode have been discussed above. A bank structure 170 is formed over the electrode layer. The bank defines pixel openings 180, where active organic materials will be deposited to form the device.

### 4. Process for Forming an Electronic Device

The backplane described herein is particularly suited to liquid deposition techniques for the organic active materials. A process for forming an organic electronic device comprises:

forming a backplane comprising:
a TFT substrate;
a thick organic planarization layer;
a multiplicity of electrode structures; and
a thin insulative inorganic bank structure defining a multiplicity of pixel openings on the electrode structures;

depositing into at least a portion of the pixel openings a first liquid composition comprising a first active material in a liquid medium.

An exemplary process for forming an electronic device includes forming one or more organic active layers in the pixel wells of the backplane described herein using liquid deposition techniques. In some embodiments, there are one or more photoactive layers and one or more charge transport layers. A second electrode is then formed over the organic layers, usually by a vapor deposition technique. Each of the charge transport layer(s) and the photoactive layer may include one or more layers. In another embodiment, a single layer having a graded or continuously changing composition may be used instead of separate charge transport and photoactive layers.

In some embodiments, there is provided an electronic device comprising:

a backplane comprising:
a TFT substrate;
a thick organic planarization layer;
a multiplicity of anode electrode structures; and
a thin insulative inorganic bank structure defining a multiplicity of pixel openings on the electrode structures;

a hole transport layer in at least the pixel openings;

a photoactive layer in at least the pixel openings;

an electron transport layer in at least the pixel openings; and

a cathode.

In some embodiments, the device further comprises an organic buffer layer between the anode and the hole transport layer. In some embodiments, the device further comprises an electron injection layer between the electron transport layer and the cathode. In some embodiments, one or more of the buffer layer, the hole transport layer, the electron transport layer and the electron injection layer are formed overall.

In an exemplary embodiment, the electrode in the backplane is an anode. In some embodiments, a first organic layer comprising organic buffer material is applied by liquid deposition. In some embodiments, a first organic layer comprising hole transport material is applied by liquid deposition. In some embodiments, first layer comprising organic buffer material and a second layer comprising hole transport material are formed sequentially. After the organic buffer layer and/or hole transport layer are formed, a photoactive layer is formed by liquid deposition. Different photoactive compositions comprising red, green, or blue emitting-materials may be applied to different pixel areas to form a full color display. After the formation of the photoactive layer, an electron transport layer is formed by vapor deposition. After formation of the electron transport layer, an optional electron injection layer and then the cathode are formed by vapor deposition.

The term “organic buffer layer” or “organic buffer material” is intended to mean electrically conductive or semiconductive organic materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Organic buffer materials may be polymers, oligomers, or small molecules, and may be in the form of solutions, dispersions, suspensions, emulsions, colloidal mixtures, or other compositions.

The organic buffer layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The organic buffer layer can comprise charge transfer compounds, and the like, such as copper phthalocyanine and the tetrathiafulvalene-tetracyanoquinodimethane system (TTF-TCNQ). In one embodiment, the organic buffer layer is made from a dispersion of a conducting polymer and a colloid-forming polymeric acid. Such materials have been described in, for example, published U.S. patent applications 2004-0102577, 2004-0127637, and 2005/205860. The organic buffer layer typically has a thickness in a range of approximately 20-200 nm.

The term “hole transport,” when referring to a layer, material, member, or structure is intended to mean such layer, material, member, or structure facilitates migration of positive charge through the thickness of such layer, material, member, or structure with relative efficiency and small loss of charge. Although light-emitting materials may also have some charge transport properties, the term “charge transport layer, material, member, or structure” is not intended to include a layer, material, member, or structure whose primary function is light emission.

Examples of hole transport materials for layer 120 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. The hole transport layer typically has a thickness in a range of approximately 40-100 nm.

“Photoactive” refers to a material that emits light when activated by an applied voltage (such as in a light emitting diode or chemical cell) or responds to radiant energy and generates a signal with or without an applied bias voltage (such as in a photodetector). Any organic electroluminescent (“EL”) material can be used in the photoactive layer, and such materials are well known in the art. The materials include, but are not limited to, small molecule organic fluorescent compounds, fluorescent and phosphorescent metal complexes, conjugated polymers, and mixtures thereof. The photoactive material can be present alone, or in admixture with one or more host materials. Examples of fluorescent compounds include, but are not limited to, naphthalene, anthracene, chrysene, pyrene, tetracene, xanthene, perylene, coumarin, rhodamine, quinacridone, rubrene, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof. The photoactive layer 1912 typically has a thickness in a range of approximately 50-500 nm.

“Electron Transport” means when referring to a layer, material, member or structure, such a layer, material, member or structure that promotes or facilitates migration of negative charges through such a layer, material, member or structure into another layer, material, member or structure. Examples of electron transport materials which can be used in an electron transport layer, include metal chelated oxinoid compounds, such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. The electron-transport layer typically has a thickness in a range of approximately 30-500 nm.

As used herein, the term “electron injection” when referring to a layer, material, member, or structure, is intended to mean such layer, material, member, or structure facilitates injection and migration of negative charges through the thickness of such layer, material, member, or structure with relative efficiency and small loss of charge. The optional electron-transport layer may be inorganic and comprise BaO, LiF, or Li₂O. The electron injection layer typically has a thickness in a range of approximately 20-100 Å.

The cathode can be selected from Group 1 metals (e.g., Li, Cs), the Group 2 (alkaline earth) metals, the rare earth metals including the lanthanides and the actinides. The cathode has a thickness in a range of approximately 300-1000 nm.

An encapsulating layer can be formed over the array and the peripheral and remote circuitry to form a substantially complete electrical device.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

What is claimed is:

1. A process for forming a backplane for an organic electronic device, the process comprising:
providing a TFT substrate;
forming a thick organic planarization layer comprising organic material having a dielectric constant of at least 2.5 over the substrate;
forming a multiplicity of electrode structures on the planarization layer; and
forming an insulative inorganic bank structure having a thickness no greater than 3000 Å defining pixel areas over the electrode structures.

2. The process of claim 1, wherein the organic planarization layer has a thickness in the range of from 0.5 to 5.0 microns.

3. The process of claim 1, wherein the planarization layer comprises a material selected from the group consisting of epoxy resins, acrylic resins, and polyimide resins.

4. The process of claim 1, wherein the insulative inorganic bank structure comprises a material selected from the group consisting of silicon oxides, silicon nitrides, and combinations thereof.

5. A backplane for an organic electronic device comprising:
a TFT substrate;
a thick organic planarization layer;
a multiplicity of electrode structures; and
an insulative inorganic bank structure having a thickness no greater than 3000 Å defining a multiplicity of pixel openings on the electrode structures.

6. The backplane of claim 5, wherein the organic planarization layer has a thickness in the range of 0.5 microns to 5.0 microns.

7. The backplane of claim 5, wherein the organic planarization layer comprises a material selected from the group consisting of epoxy resins, acrylic resins, and polyimide resins.

8. The backplane of claim 5, wherein the insulative inorganic bank structure comprises a material selected from the group consisting of silicon oxides, silicon nitrides, and combinations thereof.

9. A process for forming an organic electron device, said process comprising:
forming backplane comprising:
a TFT substrate;
a thick organic planarization layer comprising organic material having a dielectric constant of at least 2.5;
a multiplicity of electrode structures; and
an inorganic bank structure having a thickness no greater than 3000 Å defining a multiplicity of pixel openings on the electrode structures;
depositing into at least a portion of the pixel openings a first liquid composition comprising a first active material in a liquid medium.

10. The process of claim 9, wherein the organic planarization layer has a thickness in the range of 0.5 microns to 5.0 microns.

11. The process of claim 9, wherein the planarization layer comprises a material selected from the group consisting of epoxy resins, acrylic resins, and polyimide resins.

12. The process of claim 9, wherein the insulative inorganic bank structure comprises a material selected from the group consisting of silicon oxides, silicon nitrides, and combinations thereof.

13. An electronic device comprising:
a backplane comprising:
a TFT substrate;
a thick organic planarization layer;
a multiplicity of anode electrode structures; and
a thin insulative inorganic bank structure defining a multiplicity of pixel openings on the electrode structures;
a hole transport layer in at least the pixel openings;
a photoactive layer in at least the pixel openings;
an electron transport layer in at least the pixel openings; and
a cathode.

14. The device of claim 13, further comprising an organic buffer layer between the anode and the hole transport layer.

15. The device of claim 13, further comprising an electron injection layer between the electron transport layer and the cathode.
